(19) United States
(12) Patent Application Publication
(10) Pub. No.: US 2006/0267644 A1
(43) Pub. Date: Nov. 30, 2006

(54) Method and apparatus for loop filter size reduction

(76) Inventors: Edward Youssoufian, Irvine, CA (US); Tirdad Sowlati, Irvine, CA (US)

Correspondence Address: WEIDE & MILLER, LTD., 7251 W. LAKE MEAD BLVD., SUITE 530, LAS VEGAS, NV, 89128, US

(21) Appl. No.: 11/137,620

(22) Filed: May 24, 2005

(51) Int. Cl. H03L 7/06

(52) U.S. Cl. 327/156

(57) ABSTRACT

To reduce the size and cost of a loop filter, such as for example a loop filter in a phase lock loop, two or more charge pumps may be configured to inject current into two or more nodes of the loop filter. In such a configuration and for a given voltage value across the loop filter, capacitors sizes may be minimized and loop stability may be maximized. Current injection at the nodes of the loop filter increases voltage across the loop filter without a corresponding increase in capacitor size. In one embodiment the feedback loop comprises a phase or frequency detector configured to compare a feedback signal with a reference signal and based on the comparison, output or cause to be output one or more current signals to a loop filter. The current injection to the loop filter generates a voltage, which may be detected to generate a corresponding output signal.

### FIELD OF THE INVENTION

The invention relates to loop filters and, in particular, to a method and apparatus for loop filter size reduction resulting from supplemental current injection.

### RELATED ART

Feedback loops are commonly utilized in electronic systems to track or lock onto a particular desired value, such as a frequency. One such loop comprises a phase locked loop (PLL) which is a well known and widely used control loop for accurately producing, generating, or modifying a reference frequency.

While PLL have been utilized for many years, PLLs in particular, and all loops in general, are not without drawbacks. One such drawback arises from the inherently unstable nature of feedback loops and the capability for catastrophic failure in a feedback loop if instability arises. To counter the instability, a loop filter is configured to insure stable operation, such as with a capacitor to control pole and zero location. However, implementation of capacitors on integrated circuits consumes an undesirably large amount of space. As can be appreciated, reducing the size of an integrated circuit increases yield per wafer and allows for smaller circuit topologies. If off-chip capacitors are utilized, the cost also increases due to the cost of the additional components. The size of the circuit is likewise also increased.

Consequently, it may be desired to reduce the value of the capacitors or other elements in the loop filter, thereby reducing it size, while not reducing or jeopardizing the stability of the loop. The method and apparatus described below overcomes the drawbacks of the prior art by providing a stable, size optimized integrated loop filter and loop structure.

### SUMMARY

To overcome the drawbacks of the prior art and to provide additional benefits, the method and apparatus disclosed herein provides a space efficient loop filter for use in a feedback loop circuit. To achieve space efficiencies, current, or other type signal, is injected to two or more nodes of a loop filter. Injection at the two or more nodes of the loop filter results in a decrease of the filter size. In one embodiment, one or more capacitors in the loop filter may be reduced in size for a given output signal magnitude.

In one example embodiment, a phase lock loop circuit is disclosed which comprises an input configured to receive a reference signal and a phase or frequency detector configured to compare a feedback signal with the reference signal, and responsive to the comparison, generate one or more comparison signals. The circuit also utilizes one or more current sources that are configured to generate one or more current signals, responsive to the one or more comparison signals and a loop filter that is configured to receive, at two or more nodes, the one or more current signals. A signal generator is also part of the circuit and is configured to generate an output signal responsive to the voltage generated across the loop filter, wherein the output signal, or a modified version thereof, comprises the feedback signal.

In one variation of this embodiment, the one or more current sources comprise one or more charge pumps. It is contemplated that the loop filter may comprise two or more capacitors, and responsive to the injection of current at the two or more nodes, the capacitors may be smaller than in embodiments utilizing a single current injection point. In addition, the one or more current signals may comprise at least two current signals that are of different magnitude and the one or more current sources may comprise two amplifiers.

In one configuration, a space efficient phase lock loop circuit is enabled comprising a phase or frequency detector configured to compare a feedback signal to a reference signal, and responsive to the comparison, generate one or more control signals. This circuit also includes one or more charge pumps configured to generate one or more current signals responsive to the one or more control signals. A loop filter, having two or more capacitors, is part of the circuit and configured to receive, at a first node and a second node, at least one of the one or more current signals from the one or more charge pumps. A voltage is created across the loop filter and a voltage controlled oscillator configured to generate an output signal responsive to the voltage generated across the loop filter. In this embodiment, the output signal, or a modified version thereof, comprises the feedback signal.

In one variation, the two or more capacitors of the loop filter are smaller in size due to the injection of current at both the first node and the second node, as compared to a loop filter with a single current injection node. In one embodiment, the first node and the second node may be separated by a capacitor and the circuit may utilize a first charge pump to inject current to the first node and a second charge pump to inject current to the second node.

In one embodiment, a feedback loop circuit is provided which may comprise a comparator configured to compare a feedback signal to a reference signal, and responsive to the comparison, generate two or more control signals. Responsive to at least one control signal, a first charge pump may be configured to inject a first current to a first node of a space efficient loop filter. A second charge pump, responsive to at least one control signal, may be configured to inject a second current to a second node of a space efficient loop filter. The space efficient loop filter has a first node configured to receive first current and a second node configured to receive the second current. Injection of these currents to the loop filter may generate a voltage across the loop filter. A signal generator is part of the loop circuit and is configured to generate an output signal responsive to the loop filter voltage or loop filter current generated across or in the loop filter wherein the output signal, or a modified version thereof, comprises the feedback signal, and wherein injection of the first current and the second current reduces the loop filter size for a given loop filter voltage or loop filter current. Using this circuit, a reference frequency may be tracked.

In this circuit, the loop filter may further comprise two or more capacitors. In addition, the first current may be of a different magnitude than the second current. It is also contemplated that the second current may be of a greater magnitude than the first current. The signal generator may comprise a voltage controlled oscillator configured to generate an output signal having a frequency responsive to the voltage across the loop filter.

A method for tracking a reference frequency using a feedback loop is also disclosed herein. In one method of operation, this method comprises receiving a reference signal and receiving a feedback signal such that the feedback signal is identical to or related to an output signal from the loop. The method then compares one or more aspects of the reference signal to the feedback signal and generates a first current and a second current responsive to the signal comparison. The method may then inject the first current to a first node of a space efficient loop filter and inject the second current to a second node of the space efficient loop filter. To generate an output signal, the method detects the voltage generated across the space efficient loop filter and generates the output signal responsive to the detection. Use of two current injection nodes results in a smaller loop filter, thereby allowing for smaller circuit topologies and realization of the loop filter into an integrated circuit.

This method may further comprise generating one or more control signals responsive to the signal comparison such that generation of the first current and the second current are controlled by the one or more control signals. In one configuration, the space efficient loop filter is realized using two or more capacitors and wherein both the first node and the second node receive current. It is contemplated that the feedback signal may comprise a frequency modified version of the output signal. By injecting the first current and the second current to different nodes of the loop filter one or more elements in the loop filter may be made smaller.

Also disclosed herein is a loop filter configured for use in a feedback filter circuit. This loop filter is space efficient, due to the design, which provides for greater voltage across the loop filter for a given filter size, or smaller elements, such as capacitors, for a given voltage. In one embodiment, the loop filter comprises an input/output node configured to receive current from a current source and output a voltage signal. The filter also has an injection node configured to receive current from a current source and a first capacitor connected between the input/output node and the injection node. In this example embodiment, the filter further comprises a resistor connected between the second node and ground and a second capacitor connected between the input/output node and ground. In this embodiment, the injection of current at the input/output node and the injection node dictates smaller capacitor sizes as compared to injection of current at a single node for a particular output voltage.

In one variation of this filter embodiment, the input/output node is configured to connect to a signal generator that detects the voltage across the loop filter. Because of the space efficient design, the loop filter may be embodied in an integrated circuit.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates a block diagram of an example embodiment of a prior art phase lock loop.

FIG. 2 illustrates a block diagram of an example embodiment of a loop circuit with a modified loop filter and charge pump configuration.

FIG. 3 illustrates an example implementation of a loop filter having element size reduction provided by the configuration as shown.

FIG. 4 illustrates a block diagram of an alternative embodiment of a space efficient loop filter as described herein.

FIG. 5 illustrates an operational flow diagram of an example method of operation.

FIG. 6 illustrates an example environment of use for the method and apparatus described and claimed herein.

### DETAILED DESCRIPTION

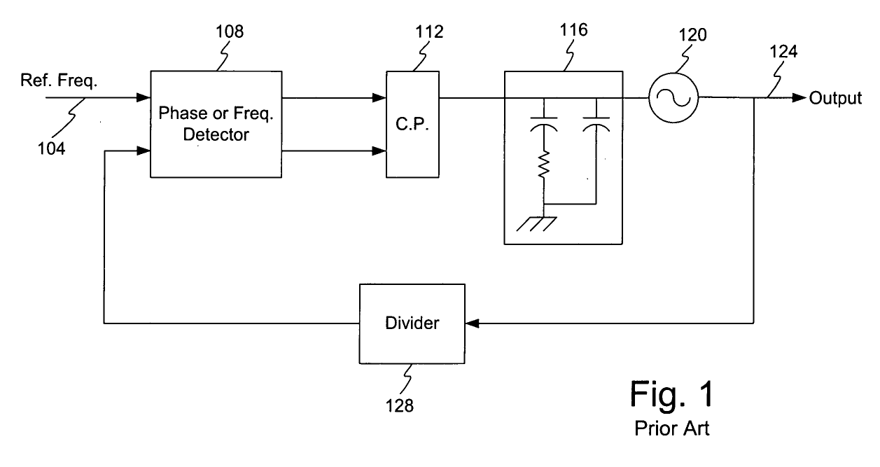

FIG. 1 illustrates an example prior art embodiment of a PLL. A reference signal input 104 connects to a phase or frequency detector 108, which also receives a feedback signal from a divider 128. In this embodiment, the output of the phase or frequency detector 108 comprises an up signal, down signal, or both, which is provided to a charge pump 112. The phase or frequency detector 108 performs a comparison of the phase or frequency between the reference signal and the feedback signal from the divider 128.

In response to the up signal, down signal, or both from the phase or frequency detector 108, the charge pump 112 outputs a current having a value based on the difference between the reference frequency and the feedback signal from the divider 128. The current from the charge pump 112 generates a voltage across the loop filter 116. In one embodiment, an up signal from the phase detector 108 increases the voltage across the loop filter while a down signal reduces the voltage. The loop filter 116 is also configured with a filter structure that stabilizes an otherwise potentially unstable feedback loop.

The voltage generated across the loop filter 116 is detected at the input to a voltage controlled oscillator (VCO) 120. Based on the value of this voltage, the output signal from the VCO 120 increases or decreases its rate of oscillation, and hence, the output frequency of the VCO output changes. The VCO output is treated as the loop output and is also provided as an input to the divider 128. The divider 128 may modify the frequency, such as increasing the frequency by a factor N, based on the configuration of the divider.

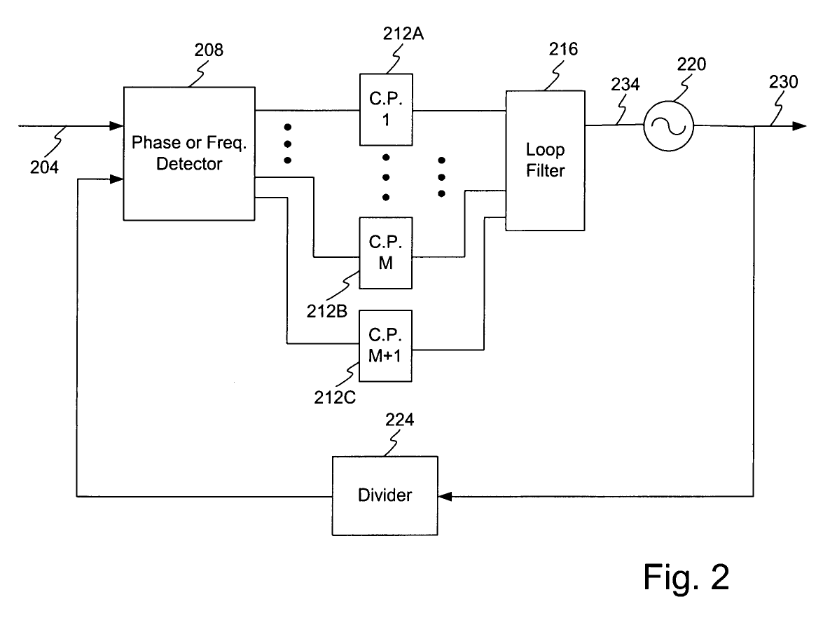

FIG. 2 illustrates a block diagram of an example embodiment of loop circuit with a modified loop filter and charge pump configuration. This is but one example embodiment of a loop circuit utilizing the invention disclosed herein and, as such, it is contemplated that one of ordinary skill in the art may generate a different embodiment, that does not depart from the scope of the claims that follow. In this example embodiment, an input 204 connects to a phase or frequency detector 208, which also receives a feedback signal from a divider 224. The phase or frequency detector may comprise any device capable of comparing the phase, frequency or both of two or more signals and in response to the comparison generating one or more outputs. Any type or configuration of phase or frequency detector 208 may be utilized as would be understood by one of ordinary skill in the art. In one embodiment, the phase or frequency detector 208 output comprises an indicator regarding the comparison between the phase, frequency, or both of the inputs to the phase or frequency detector 208. In other embodiments, aspects of the signals other than phase or frequency are compared. In one embodiment, the output of the phase or frequency detector comprises an up signal and/or down signal. These signals may comprise or be referred to as control signals. In one embodiment, the up signal and/or down signal comprise current injection signals. One or more signals may be output from the detector 208.

The phase or frequency detector 208 has one or more outputs that connect to one or more charge pumps, shown as charge pumps 212A, 212B and 212C in FIG. 2. Up to M charge pumps may be utilized where M may be any whole number. The charge pumps 212 may be configured generally similar or each charge pump may have a different configuration. The connection between the phase or frequency detector 208 and the charge pumps 212 may comprise a single conductor or two or more conductors.

The charge pumps generate output signals responsive to the input from the phase or frequency detector 208. In one embodiment, the detector outputs a first signal if the reference signal phase is ahead of the feedback signal and outputs a second signal if the phase of the reference signal is behind the feedback signal. The first signal may comprise a voltage, current, logic value, or any other indicator of the comparison of the reference signal and the feedback signal. In one embodiment, the charge pumps 212 output a current to the loop filter 216. It is contemplated that the charge pumps 212 may have a generally identical gain, or be configured with different gains, or output levels. Thus, the magnitude of the signals from the charge pumps may differ or be identical.

The loop filter 216 may comprise any type filter as would be understood to control stability or modify the output of the charge pumps 212. In one embodiment, the loop filter 216 comprises one or more capacitors, resistors, or inductors. The loop filter 216 may also comprise active elements, any passive element, or a combination of both. In one embodiment, the loop filter 216 converts the output from the charge pumps 212 to a corresponding signal suitable for input to or detection by a voltage controlled oscillator (VCO) 220, such as, for example, from a current signal to a voltage value across the filter. The voltage may correspond to the charge pump outputs, which in turn may correspond to the phase or frequency detector 208 outputs.

As is generally understood, the VCO 220 generates an output signal that has a frequency that is related to the voltage level of the input to the VCO. For example, the VCO 220 may be configured to increase the frequency of the outputs signal in response to increases in the voltage of the input signal. In addition, it is contemplated that a current controlled oscillator (CCO) may be utilized instead of the VCO as shown. Any type signal generator may be substituted for the VCO 220 to generate the output signal.

The output of the VCO 220 is provided on loop output 230 and provided to the divider 224. The divider 224, which may also be configured as a multiplier, may modify the frequency of the signal by a factor N to thereby operate in connection with the VCO 220 to scale the loop output signal based on the reference frequency. The output of the divider 224 comprises the feedback signal. Any type divider 224 (or multiplier) and VCO 220 may be utilized and, as such, the invention is not limited to any particular type of divider 224, VCO 220, filter 216, charge pump 212, or detector 208.

As an advantage over the prior art, the method and apparatus disclosed herein, and as shown in FIG. 2, may be configured to utilize more than one charge pump 212 to thereby generate a larger voltage at node 234 without the use of larger capacitors or other space consuming elements within the filter 216. Likewise, for a given voltage at node 234, one or more smaller elements may be utilized in the filter 216. This provides the advantage of smaller integrated circuits, reduces the need to utilize off-chip capacitors, and increases wafer yield. Other advantages also include potentially more stable loop operation for a given system specification.

In one embodiment, an increase in voltage at node 234 may be achieved by injecting current into one or more nodes within the loop filter. This, in turn, generates a larger voltage across the loop filter to ground thereby increasing the voltage at node 234. It is, however, contemplated that any method or configuration of loop filter 216 may be utilized that, in response to the one or more signals from the two or more signals from the one or more charge pumps may generate a larger voltage or output at node 234. As such, the claims are not limited to any one particular charge pump 212 configuration or loop filter 216 configuration.

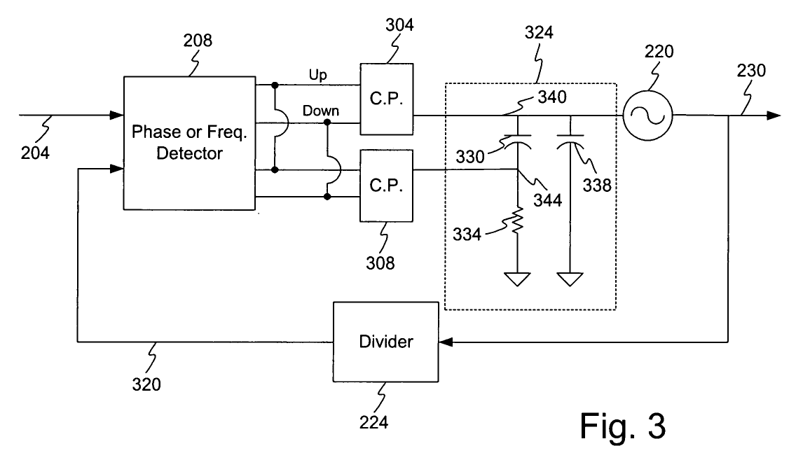

FIG. 3 illustrates an example implementation of a loop filter having element size reduction provided by the configuration as shown. As stated above, this is but one possible embodiment and is intended for purposes of discussion and should not be used to limit the claims. As compared to FIG. 2, identical or similar elements are labeled with identical reference numerals and a discussion of these elements is not repeated.

In this example embodiment, the output of the phase or frequency detector 208 comprises an up channel and a down channel signal, each of which are provided to each of the charge pump 304 and charge pump 308. In this example embodiment, the up channel signal indicates that the phase of the feedback signal, on feedback loop 320, is ahead of the input signal. In contrast, the down channel signal indicates that the phase of the signal on the feedback loop 320 is behind the input signal on input 204. In turn, these signals control the amount of current output by the charge pumps 304, 308. In this embodiment, two charge pumps 304, 308 are utilized, but in other embodiments, a greater number of charge pumps may be utilized, or a single charge pump may be utilized that is configured to operate as shown and described herein.

Based on the up channel and down channel inputs from the phase or frequency detector 208, the charge pumps 304, 308 output current signals to a filter 324. In general, in this example embodiment when the feedback signal leads in phase or frequency as compared to the input signal, then the detector 208 increases current on the up channel and decreases current on the down channel. Conversely, if the feedback signal lags in phase or frequency as compared to the reference input signal on input 204, then the detector 208 decreases current on the up channel and increases current on the down channel. As a result, the charge pumps increase or decrease current output accordingly.

In this example embodiment, the filter 324 comprises a first capacitor 330 connected to a resistor 334, which, in turn, connects to a ground node. A second capacitor 338 connects to a node 340 as shown, and to a ground node. The output of charge pump 304 connects to the node 340 while the output of charge pump 308 connects to node 344. These nodes may be referred to as a first node and a second node. In other embodiment, current may be injected to other or additional nodes. In other embodiments the filter 324 may be configured in any manner to achieve the function as set forth herein.

In particular, by increasing the current input to nodes 340, 344, the voltage created across the filter 324 increases. As compared to prior art embodiment, the second charge pump 308 supplemental current injection at node 344 creates additional voltage across the capacitor while simultaneously reducing the size of the capacitors 330, 338 required to maintain a stable loop and generate the desired voltage across the filter. Absent the current injection by the second charge pump 308, capacitor 330 would have to be undesirably large, to establish the desired voltage. Such large capacitor size requirements consume significant integrated circuit space, or may require use of an expensive and space consuming off chip capacitor. The injection of current at node 344 reduces the size requirements for the capacitors 330, 338 to a size below prior art embodiments. As a further advantage, the cost of the loop is reduced due to the cost of the second or modified charge pump 308 being less than the cost and size expense associated with undesirably large capacitors or other filter elements.

The input to the voltage controlled oscillator 220 comprises the voltage generated across the filter 324, and this voltage controls the resulting frequency or phase of the loop output signal provided on output 230. The feedback signal is generated as described above.

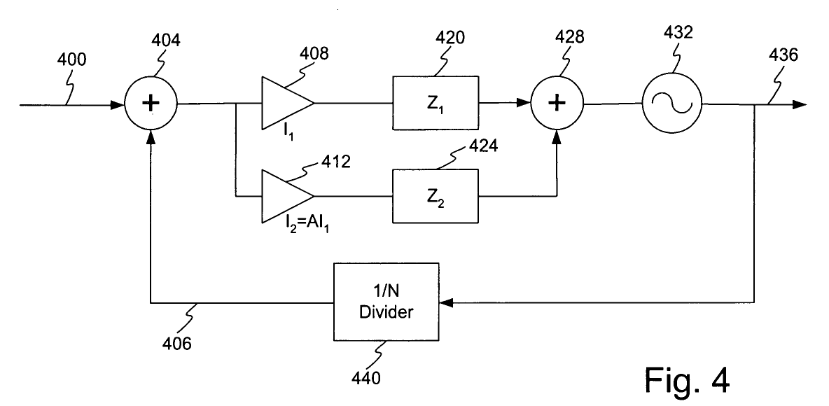

FIG. 4 illustrates a block diagram of an alternative embodiment or representation of the space efficient loop filter as described herein. In this example embodiment, the input 400 connects to summing junction 404, which also receives an input from the feedback loop 406. The summing junction 404 combines the two received signals and outputs the resulting signal to a first amplifier 408 and a second amplifier 412. The output of the junction 404 may comprise an error signal or a difference signal. The amplifiers 408, 412 may comprise any device capable of generating a signal, such as a current, voltage, or both, responsive to the input from the junction 404. In this embodiment, the gain or magnitude of the output of the second amplifier 412 is related to the output of the first amplifier by a factor A. The value for A may comprise any value which represents a gain or magnitude differential.

The output of the first amplifier 408 feeds into a first module 420 having a transfer function defined by Z₁, while the second amplifier 412 feeds into a second module 424 having a transfer function defined by Z₂. In one embodiment, the modules 420, 424 comprise filters. In one embodiment, the filters 420, 424 comprise resistor, capacitors, or both. It is contemplated that as a result of the second amplifier 412 having an output ratio defined by A, as compared to the first amplifier 408, and the use of the second module 424, the size and cost of the loop circuit may be reduced, while maintaining or increasing loop stability. In one embodiment, the size of the capacitors, if so equipped, in the modules 420, 424 may be reduced or minimized due to the injection of a signal, such as a current, to the second module 424. This allows for integration of the capacitors in to an integrated circuit.

The output of the first and second modules 420, 424 connect to a junction 428, which in this embodiment is configured to combine the two output signals. In one embodiment, the junction 428 comprises a summing junction and the output from the summing junction comprises a voltage signal which represents the difference in frequency or phase between the input signal and the signal on the feedback loop. The output of the junction 428 connects to a signal generator 432. Any type signal generator may be utilized that is configured to generate an output having a desired characteristic based on the input. In one embodiment, the generator 432 comprises a voltage controlled oscillator as described above. The signal generated by the generator 432 is provided on output 436, and is also fed back to a divider 440 which operates as described above to modify the feedback signal for comparison. The divider 440 may reduce the frequency of the output signal by a factor N.

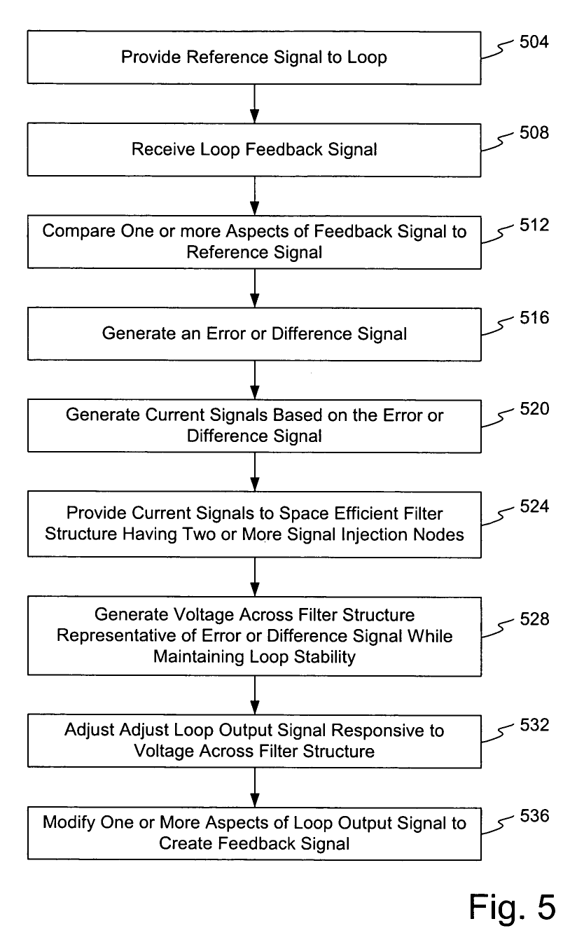

FIG. 5 illustrates an operational flow diagram of an example method of operation. This is but one possible method of operation and, as such, it is contemplated that other methods of operation may be enabled depending on the particulars of the loop, filter, or charge pump being utilized.

At a step 504, the operation provides the reference signal to the loop. The reference signal may be provided from any source, such as a crystal or any other device capable of generating a reference signal. The loop may comprise a phase lock loop or any other type of feedback loop. At a step 508, the operation receives the loop feedback signal and at a step 512, the operation compares one or more aspects of the feedback signal to the reference signal. Any aspect may be compared, including, but not limited to, phase, frequency, or both. In one embodiment, the comparison is performed by a frequency or phase detector that detects the phase or frequency and performs the comparison.

Based on the comparison of step 512, the operation generates an error or difference signal representing the difference, of some aspect, between the feedback signal and the reference signal. This occurs at step 516. At step 520, the operation generates a current signal based on the error or difference signal. One or more current signals may be generated and if more than one current signal is generated, the signal may comprise different or identical values or magnitudes. In one embodiment charge pumps generate the current signals. At a step 524, the operation provides or injects the current signals to a space efficient filter structure having two or more signal injection nodes. The use of two or more injection points provides the advantage of maintaining desired voltage across the filter structure(s) while reducing the size and cost of the filter structure itself.

At a step 528, the current injection generates a voltage across the filter structure. The voltage may be generated at a desired level while maintaining loop stability. This voltage is utilized, at a step 532, to generate or adjust a loop output signal. In one embodiment, a voltage controlled oscillator detects the voltage and generates a signal responsive to the voltage level. In other embodiments, other circuits or devices may be utilized to generate the output signal. The loop output may comprise a local oscillator signal. Thereafter, at a step 536, the system modifies one or more aspects of the loop output to create the feedback signal. In one embodiment, this comprises dividing the frequency of the output signal to create the feedback signal.

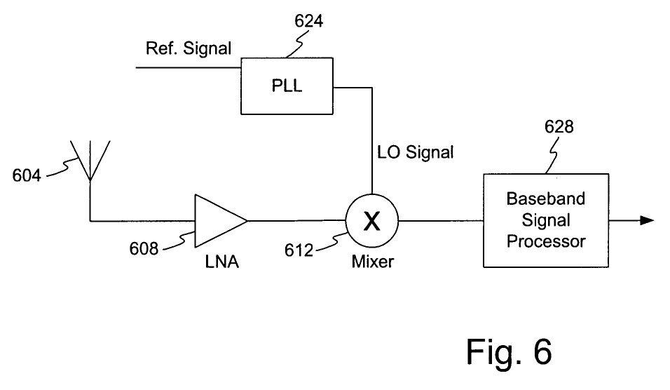

FIG. 6 illustrates an example environment of use for the method and 15 apparatus described and claimed herein. This is but one possible example environment, and as such, one of ordinary skill in the art may apply the principles disclosed herein to other environments. By way of example, any control loop may benefit from the smaller foot print of a system embodied as disclosed herein, or the increased stability resulting from this design, for a given filter size, where both size and stability and determined primarily by capacitor values.

In the embodiment of FIG. 6, a communication device is shown as having an antenna 604 connected to a low noise amplifier 608. The output of the low noise amplifier 608 connects to a mixer 612, which also receives a local oscillator signal from a phase lock loop (PLL) 624 as shown. The PLL 624 receives a reference signal, from which the PLL output is generated. The output of the mixer 612 comprises a baseband signal, which feeds into a baseband signal processor 628 configured to process the baseband signal of interest.

In operation, the antenna 604 is generally configured or tuned to receive one or more signals in one or more frequency bands. It is contemplated that the signals received by the antenna may comprise one or more modulated signals of interest and one or more disturber or interferer signals. The amplifier 608 increases the magnitude of the lower power signal from the antenna while the mixer 612 processes the received signal, with the local oscillator signal to isolate the desired baseband signal. Thus, the mixer may perform both demodulation and signal isolation. A highly accurate local oscillator signal is required for operation of mixer 612. Upon receiving the isolated signal of interest, the baseband processor 628 performs one or more processing steps to manipulated the signal into a desired format. The method and apparatus described herein may be utilized to enable the PLL 624.

While various embodiments of the invention have been described, it will be apparent to those of ordinary skill in the art that many more embodiments and implementations are possible that are within the scope of this invention.

What is claimed is:

1. A phase lock loop circuit comprising:
an input configured to receive a reference signal;
a phase or frequency detector configured to compare a feedback signal with the reference signal, and responsive to the comparison, generate one or more comparison signals;
one or more current sources configured to generate one or more current signals, responsive to the one or more comparison signals;
a loop filter configured to receive, at two or more nodes, the one or more current signals; and
a signal generator configured to generate an output signal responsive to the voltage generated across the loop filter, wherein the output signal, or a modified version thereof, comprises the feedback signal.

2. The circuit of claim 1, wherein the one or more current sources comprise one or more charge pumps.

3. The circuit of claim 1, wherein the loop filter comprises two or more capacitors, and responsive to the injection of current at two or more nodes, the capacitors may be smaller than in embodiments utilizing a single current injection point.

4. The circuit of claim 1, wherein the signal generator comprises a voltage controlled oscillator.

5. The circuit of claim 1, wherein the one or more current signals comprise at least two current signals that are of different magnitude.

6. The circuit of claim 1, wherein the one or more current sources comprise two amplifiers.

7. A space efficient phase lock loop circuit comprising:
a phase or frequency detector configured to compare a feedback signal to a reference signal, and responsive to the comparison, generate one or more control signals;
one or more charge pumps configured to generate one or more current signals responsive to the one or more control signals;
a loop filter, having two or more capacitors, configured to receive, at a first node and a second node, at least one of the one or more current signals from the one or more charge pumps; and
a voltage controlled oscillator configured to generate an output signal responsive to the voltage generated across the loop filter wherein the output signal, or a modified version thereof, comprises the feedback signal.

8. The circuit of claim 7, wherein the two or more capacitors of the loop filter are smaller in size due to the injection of current at both the first node and the second node, as compared to a loop filter with a single current injection node.

9. The circuit of claim 7, wherein the first node and the second node are separated by a capacitor.

10. The circuit of claim 7, wherein the circuit utilizes a first charge pump to inject current to the first node and a second charge pump to inject current to the second node.

11. The circuit of claim 7, further comprising a divider configured to process the output signal to create the feedback signal.

12. A feedback loop circuit comprising:
a comparator configured to compare a feedback signal to a reference signal, and responsive to the comparison, generate two or more control signals;
a first charge pump, responsive to at least one control signal, configured to inject a first current to a first node of a space efficient loop filter;
a second charge pump, responsive to at least one control signal, configured to inject a second current to a second node of a space efficient loop filter;
a space efficient loop filter, having a first node configured to receive first current and a second node configured to receive the second current; and
a signal generator configured to generate an output signal responsive to the loop filter voltage or loop filter current generated across or in the loop filter wherein the output signal, or a modified version thereof, comprises the feedback signal, and wherein injection of the first current and the second current reduces the loop filter size for a given loop filter voltage or loop filter current.

13. The circuit of claim 12, wherein the loop filter further comprises two or more capacitors.

14. The circuit of claim 12, wherein the first current is of different magnitude than the second current.

15. The circuit of claim 12, wherein the comparator comprises a phase or frequency detector.

16. The circuit of claim 12, wherein the loop filter comprises resistors and capacitors.

17. The circuit of claim 12, wherein the second current is a greater magnitude than the first current.

18. The circuit of claim 12, wherein the signal generator comprises a voltage controlled oscillator configured to generate an output signal having a frequency responsive to the voltage across the loop filter.

19. A method for tracking a reference frequency using a feedback loop:
receiving a reference signal;
receiving a feedback signal, wherein the feedback signal is identical to or related to an output signal;
comparing one or more aspects of the reference signal to the feedback signal;
generating a first current and a second current responsive to the comparing;
injecting the first current to a first node of a space efficient loop filter;
injecting the second current to a second node of the space efficient loop filter;
detecting the voltage generated across the space efficient loop filter; and
generating the output signal responsive to the detecting.

20. The method of claim 19, further comprising generating one or more control signals responsive to the comparing and wherein generation of the first current and the second current are controlled by the one or more control signals.

21. The method of claim 19, wherein the space efficient loop filter is realized using two or more capacitors and wherein both the first node and the second node receive current.

22. The method of claim 19, wherein the feedback signal comprises a frequency modified version of the output signal.

23. The method of claim 19, wherein the space efficient loop filter is space efficient due to injection of the first current and the second current to different nodes of the loop filter thereby allowing for use of one or more smaller elements in the loop filter.

24. The method of claim 19, wherein the first current and the second current are of different magnitude.

25. A loop filter configured for use in feedback filter circuit:
an input/output node configured to receive current from a current source and output a voltage signal;
an injection node configured to receive current from a current source;
a first capacitor connected between the input/output node and the injection node;
a resistor connected between the second node and ground;
a second capacitor connected between the input/output node and ground, wherein injection of current at the input/output node and the injection node enables smaller capacitor sizes as compared to injection at a single node for a particular output voltage.

26. The filter of claim 25, wherein the input/output node is configured to connect to a signal generator that detects the voltage across the loop filter.

27. The filter of claim 25, wherein the loop filter is embodied in an integrated circuit.

28. The filter of claim 25, wherein the current injected to the input/output node is different in magnitude than the current injected to the injection node.

29. The filter of claim 25, wherein the loop filter is configured to maintain stability in a phase lock loop.
